(19) United States
(12) Patent Application Publication
(10) Pub. No.: US 2024/0194727 A1
(43) Pub. Date: Jun. 13, 2024

(54) METHOD OF MANUFACTURING AN OPTOELECTRONIC DEVICE COMPRISING A LED AND A PHOTODIODE

(71) Applicant: Commissariat à I'Énergie Atomique et aux Énergies Alternatives, Paris (FR)

(72) Inventors: Julia Simon, Grenoble Cedex 9 (FR); Fabian Rol, Grenoble Cedex 9 (FR); Patrick Le Maitre, Grenoble Cedex 9 (FR)

(73) Assignee: Commissariat à I'Énergie Atomique et aux Énergies Alternatives, Paris (FR)

(21) Appl. No.: 18/530,054

(22) Filed: Dec. 5, 2023

(30) Foreign Application Priority Data
Dec. 7, 2022 (FR) 2212873

(51) Int. Cl. H01L 27/15

(52) U.S. Cl. CPC H01L 27/156

(57) ABSTRACT

A method of manufacturing an optoelectronic device including at least one LED and at least one photodiode, including the following steps: a) forming a semiconductor support stack including at least one doped semiconductor layer; b) simultaneously forming, during a common epitaxy step, an active emission semiconductor stack of the LED and an active reception semiconductor stack of the photodiode; c) forming trenches delimiting first and second support pads; and d) porosifying the doped semiconductor layer in the first support pad without porosifying this layer in the second support pad, or porosifying the doped semiconductor layer in the second support pad without porosifying this layer in the first support pad.

### CROSS REFERENCE TO RELATED APPLICATIONS

This application claims priority to French application number 2212873, filed Dec. 7, 2022, the contents of which is incorporated herein by reference in its entirety.

### TECHNICAL FIELD

The present disclosure generally concerns the field of optoelectronic devices. It more particularly aims at the forming of an optoelectronic device comprising at least one light-emitting diode (LED), and at least one photodiode. It particularly aims at the simultaneous forming, by means of a common epitaxy step, of an active LED emission stack and of an active photodiode reception stack, intended to operate in a same wavelength range.

### PRIOR ART

There have already been provided, for example in the field of optical communication systems, devices comprising one or a plurality of LEDs configured to emit light signals, and one or a plurality of photodiodes configured to receive and measure signals emitted by the LEDs.

It would be desirable to be able to at least partly improve certain aspects of these systems.

It would be desirable to be able to simultaneously form, by means of a common epitaxy step, an active emission stack of the LED and an active reception stack of the photodiode.

### SUMMARY OF THE INVENTION

For this purpose, an embodiment provides a method of manufacturing an optoelectronic device comprising at least one LED and at least one photodiode, comprising the following successive steps:
a) forming, by epitaxy, an active emission and reception semiconductor stack common to the LED and to the photodiode;
b) forming trenches vertically extending through the active stack and laterally delimiting the LED and the photodiode, wherein the trenches are arranged so that the lateral dimensions of the LED are smaller than the lateral dimensions of the photodiode.

According to an embodiment, the trenches are arranged so that the lateral dimensions of the LED are at least twice smaller than the lateral dimensions of the photodiode.

According to an embodiment, the trenches are arranged so that the lateral dimensions of the LED are at least four times smaller than the lateral dimensions of the photodiode.

According to an embodiment, the trenches are arranged so that the lateral dimensions of the LED are smaller than 4 μm.

According to an embodiment, the method comprises, between step a) and step b), a step of transfer and of bonding of the active stack onto a surface of an integrated control circuit previously formed inside and on top of a semiconductor substrate.

According to an embodiment, at the transfer and bonding step, the active stack is bonded to said surface of the integrated control circuit by molecular bonding.

According to an embodiment, at the end of the transfer and bonding step, the active stack continuously extends over the entire surface of the integrated control circuit.

According to an embodiment, the active semiconductor stack comprises one or a plurality of type-III-V or II-VI semiconductor alloys.

Another embodiment provides an optoelectronic device comprising at least one LED and at least one photodiode, each comprising an active emission and reception semiconductor stack of same nature and of same composition, where the lateral dimensions of the LED are smaller than the lateral dimensions of the photodiode.

According to an embodiment, the device further comprises an integrated control circuit on a surface of which are bonded the LED and the photodiode, the integrated control circuit being adapted to driving the LED with a higher current density than that of the photodiode.

According to an embodiment, the integrated control circuit is adapted to driving the LED with a current density at least ten times higher than that of the photodiode.

Another embodiment provides a method of manufacturing an optoelectronic device comprising at least one LED and at least one photodiode, comprising the following steps:
a) forming a support semiconductor stack comprising at least one doped semiconductor layer;
b) simultaneously forming, during a common epitaxy step, an active emission semiconductor stack of the LED and an active reception semiconductor stack of the photodiode;
c) forming trenches vertically extending through the support stack and laterally delimiting at least one first support pad and at least one second support pad, wherein, at the end of steps b) and c), the active emission semiconductor stack of the LED covers the first support pad and the active reception stack of the photodiode covers the second support pad,
the method further comprising, après step c), a step d) of porosification of said doped semiconductor layer in the first support pad without porosifying said doped semiconductor layer in the second support pad, or a step of porosification of said doped semiconductor layer in the second support pad without porosifying said doped semiconductor layer in the first support pad.

According to an embodiment, step c) of forming of the trenches through the support stack and step d) of porosification of the doped semiconductor layer are implemented before step b) of epitaxy of the active emission semiconductor stack of the LED and of the active reception semiconductor stack of the photodiode, and, during step d), said doped semiconductor layer is porosified in the second support pad and is not porosified in the first support pad.

According to an embodiment, step c) of forming of the trenches through the support stack is implemented after step b) of epitaxy of the active emission semiconductor stack of the LED and of the active reception semiconductor stack of the photodiode, and, during step d), said doped semiconductor layer is porosified in the first support pad and not in the second support pad.

According to an embodiment, at step d), the sides of the doped semiconductor layer in the second pad are placed into contact with the electrolyte, while the sides of the doped semiconductor layer in the first pad are protected from the contact with the electrolyte by a protection layer.

According to an embodiment, at step d), the sides of the doped semiconductor layer in the first pad are placed into contact with an electrolyte, while the sides of the doped semiconductor layer in the second pad are protected from the contact with the electrolyte by a protection layer.

According to an embodiment, at step d), a bias current is applied through said doped semiconductor layer.

According to an embodiment, the method comprises, after steps b) and d), a step of transfer and of bonding of the LED and of the photodiode onto a surface of an integrated control circuit previously formed inside and on top of a semiconductor substrate.

According to an embodiment, during the transfer and bonding step, the LED and the photodiode are bonded to the surface of the integrated control circuit by molecular bonding.

According to an embodiment, the trenches are arranged so that the lateral dimensions of the LED are smaller than the lateral dimensions of the photodiode.

According to an embodiment, the active emission semiconductor stack of the LED and the active reception semiconductor stack of the photodiode comprise one or a plurality of type-III-V or II-VI semiconductor alloys.

Another embodiment provides an optoelectronic device comprising at least one LED comprising an active emission semiconductor stack and at least one photodiode comprising an active reception semiconductor stack, the device further comprising a doped semiconductor layer in front of the LED and of the photodiode, wherein the doped semiconductor layer is porous in front of the LED and non-porous in front of the photodiode, or wherein the doped semiconductor layer is porous in front of the photodiode and non-porous in front of the LED.

According to an embodiment, the device further comprises an integrated control circuit on a surface of which are bonded the LED and the photodiode, the integrated control circuit being adapted to driving the LED with a current density higher than that of the photodiode.

According to an embodiment, the integrated control circuit is adapted to driving the LED with a current density at least ten times higher than that of the photodiode.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1A, FIG. 1B, FIG. 1C, and FIG. 1D are cross-section views illustrating steps of an example of implementation of a method of manufacturing an optoelectronic device according to a first embodiment;

FIG. 2A, FIG. 2B, FIG. 2C, FIG. 2D, FIG. 2E, and FIG. 2F are cross-section views illustrating steps of an example of implementation of a method of manufacturing an optoelectronic device according to a second embodiment;

FIG. 3A, FIG. 3B, FIG. 3C, FIG. 3D, and FIG. 3E are cross-section views illustrating steps of an example of implementation of a method of manufacturing an optoelectronic device according to a third embodiment; and

FIG. 4 is a diagram illustrating the response of an active LED emission stack and of an active photodiode reception stack formed by means of a common epitaxy step.

### DESCRIPTION OF EMBODIMENTS

Like features have been designated by like references in the various figures. In particular, the structural and/or functional features that are common among the various embodiments may have the same references and may dispose identical structural, dimensional and material properties.

For the sake of clarity, only the steps and elements that are useful for the understanding of the described embodiments have been illustrated and described in detail. In particular, the forming of the electric connections and of the circuits for controlling the LEDs and the photodiodes of the described devices has not been detailed, the described embodiments being compatible with usual embodiments of these elements or the forming of these elements being within the abilities of those skilled in the art based on the indications of the present description. Further, the applications likely to take advantage of the described embodiments have not been detailed, and the described embodiments can advantageously be used for any application comprising one or a plurality of LEDs and one or a plurality of photodiodes intended to operate in a same wavelength range, for example a wavelength range of visible, ultraviolet, or near-infrared light.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms qualifying absolute positions, such as terms “edge”, “back”, “top”, “bottom”, “left”, “right”, etc., or relative positions, such as terms “above”, “under”, “upper”, “lower”, etc., or to terms qualifying directions, such as terms “horizontal”, “vertical”, etc., it is referred, unless specified otherwise, to the orientation of the drawings.

Unless specified otherwise, the expressions “about”, “approximately”, “substantially”, and “in the order of” signify plus or minus 10%, preferably of plus or minus 5%.

According to an aspect of the described embodiments, there is provided a method of manufacturing an optoelectronic device where there are simultaneously formed, during a same epitaxy step, an active emissive LED stack and an active photosensitive photodiode stack.

An advantage lies in the cost decrease with respect to methods comprising distinct specific epitaxy steps to successively form the active emissive LED stack and the active photosensitive photodiode stack.

The LED and the photodiode may be integrated in monolithic fashion in a same optoelectronic chip, or be separated by cutting at the end of the process to be integrated in distinct chips, for example intended to be assembled within a same optoelectronic device.

The active emissive LED stack and the active photosensitive photodiode stack are for example inorganic semiconductor stacks, for example based on type-III-V semiconductor materials, for example based on group-III nitrides, for example with gallium, aluminum, indium, or an alloy based on one or a plurality of these materials. As a variant, the active emissive LED stack and the active photosensitive photodiode stack are based on type-II-VI semiconductor materials, for example ZnCdSe (zinc-cadmium-selenium).

A same active stack based on gallium nitride may for example be used in emission as an active LED stack, or in reception, as an active photodiode stack. The photodiode then advantageously exhibits a very low dark current and a narrow optical reception bandwidth, which enables to obtain a very good signal-to-noise ratio.

However, a difficulty then lies in the fact that the optimal emission wavelength of the LED (emission peak) is shifted upwards by a few tens of nanometers, typically in the order of 20 nm for an active stack based on gallium nitride (GaN), for example based on indium gallium nitride (InGaN), with respect to the optimal reception wavelength of the photodiode (absorption peak). This is the Stokes shift, which originates in particular from the bond energy of electron-hole pairs. This affects the photodiode sensitivity in the emission wavelength range of the LED, and accordingly the efficiency of the LED-photodiode system.

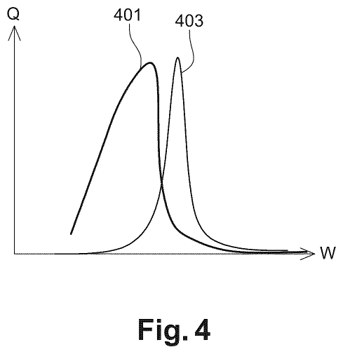

This phenomenon is particularly illustrated in FIG. 4.

FIG. 4 is a diagram showing the variation, according to the wavelength W (in abscissas), of the quantum efficiency Q in reception (curve 401) and in emission (curve 403) of an active diode stack based on gallium nitride (GaN), for example based on indium gallium nitride (InGaN).

According to an aspect of a first embodiment, it is provided to form, by epitaxy, an active semiconductor stack common to the LED and to the photodiode, and then to form trenches vertically extending through the active stack and laterally delimiting the LED and the photodiode. According to the first embodiment, the LED has lateral dimensions smaller than those of the photodiode. This enables to release the mechanical stress in the active LED stack more strongly than in the active photodiode stack. This results in a decrease of the internal electric field in the active LED stack as compared with the internal electric field in the active photodiode stack. This decrease of the internal electric field in the active LED stack results in shifting downwards (it is spoken of a blue shift) the emission peak of the LED. This enables to at least partially compensate for the Stokes shift between the emission peak and the absorption peak of the active stack. Thus, the emission peak of the LED comes closer to the absorption peak of the photodiode, which improves the system efficiency.

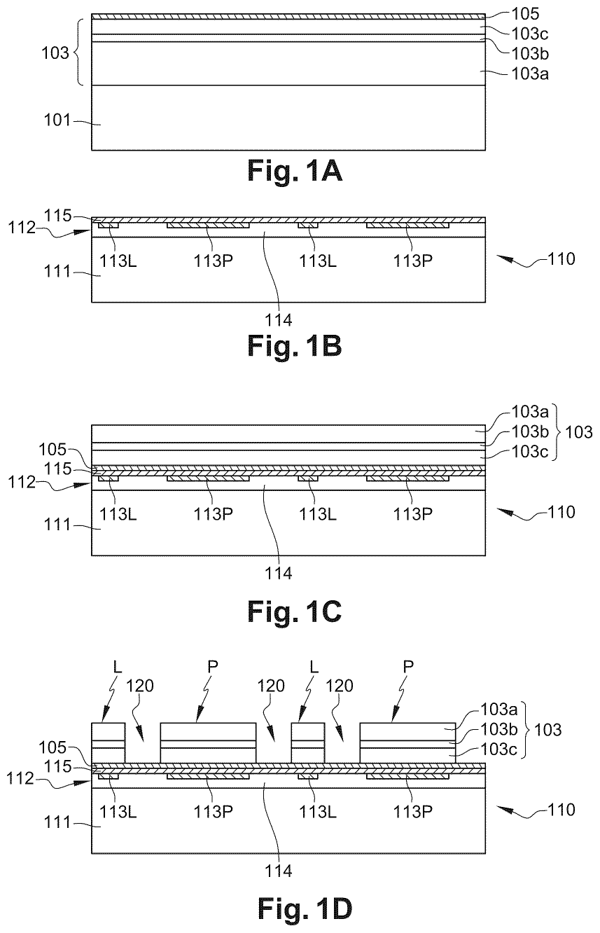

FIGS. 1A to 1D are cross-section views schematically illustrating steps of an example of implementation of a method of manufacturing an optoelectronic device according to the first embodiment.

FIG. 1A illustrates a structure comprising an active emission and reception semiconductor stack 103 arranged on the upper surface of a support substrate 101.

The active stack 103 comprises for example a doped semiconductor layer 103a of a first conductivity type, for example of type N, coating the upper surface of substrate 101, an active layer 103b coating the surface of layer 103a opposite to substrate 101, that is, its upper surface in the orientation of FIG. 1A, and a doped semiconductor layer 103c of a second conductivity type, for example type P, coating the surface of the layer 103b opposite to layer 103a, that is, its upper surface in the orientation of FIG. 1A. As an example, layer 103b is in contact, by its lower surface, with the upper surface of layer 103a, and, by its upper surface, with the lower surface of layer 103c.

The layers 103a, 103b, and 103c of active stack 103 for example each continuously extend with a substantially uniform thickness over the entire surface of substrate 101.

Layers 103a, 103b, and 103c are for example successively formed by epitaxy on the upper surface of support substrate 101.

As an example, support substrate 101 is made of sapphire or of silicon. The semiconductor layers 103a and 103c of active stack 103 are for example made of gallium nitride. Active layer 103b comprises for example a stack of layers each forming a quantum well, for example based on indium gallium nitride (InGaN).

A buffer layer, not shown, may form an interface between the upper surface of substrate 101 and the lower surface of lower layer 103a.

FIG. 1A further illustrates a step of deposition, on the upper surface of active stack 103, of a metal layer 105. In the shown example, layer 105 continuously extends with a substantially uniform thickness over the entire upper surface of active stack 103. As an example, layer 105 is in contact, by its lower surface, with the upper surface of the upper layer 103c of the active stack.

FIG. 1B schematically shows an integrated control circuit 110, previously formed inside and on top of a semiconductor substrate 111, for example a silicon substrate. In this example, control circuit 110 comprises, on its upper surface side, for each of the LEDs of the device, a metal connection pad 113L intended to be connected to one of the electrodes (anode or cathode) of the LED, to be able to control a current flowing through the LED and/or apply a voltage across the LED. Control circuit 110 further comprises in this example, on its upper surface side, for each of the photodiodes of the device, a metal connection pad 113P intended to be connected to one of the electrodes (anode or cathode) of the photodiode, to be able to read an electric signal representative of the intensity of a light radiation received by the photodiode in its wavelength range of sensitivity.

Control circuit comprises for example, for each LED, connected to the metal pad 113L dedicated to the LED, an elementary control cell comprising one or a plurality of transistors, enabling to control the current flowing through the LED and/or a voltage applied across the LED, and, for each photodiode, connected to the metal pad 113P dedicated to the photodiode, an elementary readout cell comprising one or a plurality of transistors, enabling to read an electric signal representative of the intensity of a light radiation received by the photodiode in its wavelength range of sensitivity. The readout circuit comprises for example a transimpedance amplifier used to amplify the current of the photodiode.

Control circuit 110 is for example formed in CMOS technology. Metal pads 113L, 113P may be laterally surrounded with an insulating material 114, for example silicon oxide, so that control circuit 110 has a substantially planar upper surface comprising an alternation of metal regions 113 and of insulating regions 114. The contact on the electrodes of the LEDs or of the photodiodes not connected to pads 113L, 113P may be taken collectively, for example in a peripheral region of control circuit 110, via one or a plurality of connection pads (not shown in the drawing) of control circuit 110. As an example, control circuit 110 comprises, on the upper surface side of substrate 111, a stack of insulating and conductive levels forming an interconnection network 112 particularly comprising connection pads 113L, 113P, the upper surface of interconnection network 112 defining the upper surface of circuit 110.

FIG. 1B further illustrates a step of deposition, on the upper surface of integrated control circuit 110, of a metal layer 115. In the shown example, layer 115 continuously extends with a substantially uniform thickness over the entire upper surface of circuit 110. As an example, layer 115 is in contact, by its lower surface, with the upper surface of the interconnection network 112 of control circuit 110.

Layer 115 is for example made of the same material as layer 105. As an example, layers 105 and 115 each comprise an upper layer called bonding layer. The bonding layers of layers 105 and 115 are preferably made of a same material, for example of titanium.

FIG. 1C illustrates the structure obtained at the end of a step of transfer of the active LED and photodiode stack 103 onto the upper surface of control circuit 110. For this purpose, the structure of FIG. 1A may be flipped, and then transferred onto the structure of FIG. 1B to place into contact the surface of metal layer 105 opposite to substrate 101 (that is, its lower surface in the orientation of FIG. 1C, corresponding to its upper surface in the orientation of FIG. 1A) with the surface of metal layer 115 opposite to substrate 111 (that is, its upper surface in the orientation of FIGS. 1B and 1C). During this step, active stack 103 is bonded to control circuit 110. As an example, the bonding of active stack 103 to control circuit 110 may be obtained by molecular bonding between the two surfaces placed into contact. As a variant, the bonding of the two surfaces may be performed by thermocompression, eutectic bonding, or by any other adapted bonding technique.

Once the bonding has been performed, support substrate 101 is removed to expose the upper surface (in the orientation of FIG. 1C) of the semiconductor layer 103c of active stack 103. Substrate 101 is for example removed by grinding and/or etching from its surface opposite to active stack 103. As a variant, in the case of a transparent substrate 101, for example a sapphire substrate, substrate 101 may be separated from active stack 103 by means of a laser beam projected through substrate 101 from its surface opposite to active stack 103 (method of laser lift-off type). More generally, any other method enabling to remove substrate 101 may be used. After the removal of the substrate, an additional etch step may be provided to remove possible buffer layers remaining on the upper surface side of semiconductor layer 103c. Further, a portion of the thickness of layer 103c may be removed, for example by etching. At the end of this step, active stack 103 substantially coats the entire surface of control circuit 110, with no discontinuity. As an example, the thickness of active stack 103 at the end of the step of FIG. 1D is in the range from 0.5 to 2 μm.

At the end of this step, the mechanical stress of active epitaxial stack 103 is partially transferred into the substrate 111 of control circuit 110.

FIG. 1D illustrates a step subsequent to the step of FIG. 1C, during which trenches 120 are formed in active stack 103, from its upper surface, for example by lithography and then etching, to delimit one or a plurality of LEDs L and one or a plurality of photodiodes P, each corresponding to an island- or mesa-shaped portion of active stack 103. In the shown example, trenches 120 vertically extend along the entire height of active stack 103 and emerge onto the upper surface of metal layer 105. Trenches 120 may be aligned on marks previously formed on control circuit 110. In the shown example, each LED L is located, in vertical projection, in front of a single metal pad 113L of control circuit 110, and each photodiode P is located, in vertical projection, in front of a single metal pad 113P of control circuit 110. As an example, each LED L and each photodiode P has, in top view, a substantially square or rectangular shape. Trenches 120 for example form, in top view, a grid or a checkered pattern laterally separating from one another the LEDs L and the photodiodes P of the device.

The trenches can then be continued through metal layers 105 and 115 to individualize the electric connections on the lower semiconductor layer 103c of the active stack 103 of each LED L and of each photodiode P. Subsequent steps can then be implemented to recover an individual or common electric contact on the upper semiconductor layer 103a of the active stack 103 of each LED L and of each photodiode P. These steps have not been detailed and are within the abilities of those skilled in the art based on the indications of the present description. As an example, these steps are similar to what has been described in patent application WO2017194845 or in patent application WO2019092357 previously filed by the applicant.

During the step of FIG. 1D of etching of active stack 103, an additional relaxation of the mechanical stress present in active epitaxial stack 103 occurs from the edges of the etched islands or mesas. This relaxation depends on the size of the islands or mesas. In particular, islands or mesas of small dimensions exhibit a significant relaxation of the stress, while islands or mesas of larger dimensions keep a relatively high mechanical stress. The relaxation may further depend on the nature of the substrate, which may for example comprise a stack of a gallium nitride layer on a silicon layer, or a stack of a gallium nitride layer on a sapphire layer, or a stack of a porous gallium nitride layer on a silicon layer.

According to an aspect of the first embodiment, it is provided to define:
LEDs L having relatively low lateral dimensions to obtain a significant relaxation of the mechanical stress in active stack 103 and accordingly a relatively significant downward shift of the emission peak, and
photodiodes P having relatively high lateral dimensions to obtain a less significant relaxation of the mechanical stress in active stack 103 and accordingly a relatively low downward shift of the absorption peak.

This enables to at least partially compensate for the Stokes shift naturally present between the emission peak and the absorption peak of active stack 103.

As an example, the islands or mesas forming LEDs L have lateral dimensions smaller than or equal to 5 μm, for example smaller than or equal to 4 μm, for example smaller than or equal to 2 μm. This enables to obtain a quasi-total relaxation of the active stack during the etching of the LED. The islands or mesas forming photodiodes P have lateral dimensions greater than those of the LEDs, for example at least twice greater than those of the LEDs, for example at least four times greater than those of the LEDs, to keep relatively high mechanical stress in the active stack 103 of photodiodes P.

As an example, non-limiting, for an active stack based on GaN and for square LEDs L having an approximately 1-μm side length and photodiodes P having a side length from 8 to 10 μm, an alignment of the emission peak of LEDs L on the absorption peak of photodiodes P can be observed.

The described embodiments are not limited to the example of arrangement of LEDs L and of photodiodes P shown in FIG. 1D. As an example, the device may comprise, on a first portion of the surface of integrated control circuit 110, a plurality of LEDs L, for example identical (to within manufacturing dispersions), for example arranged in an array in rows and columns, for example with a constant pitch between LEDs. The device may further comprise, on a second portion of the surface of integrated control circuit 110, a plurality of photodiodes P, for example identical (to within manufacturing dispersions), for example arranged in an array of rows and columns, for example with a constant pitch between photodiodes. The pitch between LEDs in the first region is for example identical to the pitch between photodiodes in the second region. The lateral dimensions of the LEDs of the first region are however smaller than the lateral dimensions of the photodiodes of the second region.

In addition to the differentiated size of LEDs L with respect to photodiodes P, another parameter enabling to decrease the wavelength shift between the emission peak of the LEDs and the absorption peak of the photodiodes is the density of charge carriers in the active stack and particularly in the quantum wells of active layer 103b. More particularly, a high carrier density will result in shielding the electric field present in the active stack, and accordingly of shifting upwards the optimal operating wavelength of the active stack.

Thus, advantageously, control circuit 110 is configured to drive LEDs L at higher voltages than photodiodes P. This enables to obtain a higher carrier density in LEDs L than in photodiodes P, and accordingly to decrease the shift between the emission peak of LEDs L and the absorption peak of photodiodes P. As an example, the drive voltages are selected to have a carrier density in LEDs L at least twice higher, for example at least five times higher, for example in the order of ten times higher, than in photodiodes P.

The value of the wavelength shift linked to the increase of the current density in the LED depends on the structure of the active stack, and particularly on the width of the quantum wells of active layer 103b. In particular, the wider the wells, the higher the shielding of the electric field linked to the increase of the carrier density will be, and accordingly the higher the downward shift of the optimal emission wavelength of the LED linked to the increase of the carrier density will be. The increase of the width of the wells however causes a longer radiative recombination time, which may be damageable for communication applications requiring a short recombination time. Those skilled in the art will be capable of selecting the adapted tradeoff according to the needs of the application. As an illustrative example, non-limiting, for a LED comprising quantum wells made of InGaN having a 4-nm thickness with an indium content of 14.3%, driving LED with a current density in the order of 100 A/cm² results in a blue shift of the emission peak of approximately 6 nm with respect to a driving of the same LED at a current density in the order of 10 A/cm².

To fully compensate for the Stokes shift, one may for example provide combining the mechanical relaxation effect described hereabove by providing LEDs smaller than the photodiodes, and the effect of shielding of the field by the carriers by providing a current density higher in the LEDs than in the photodiodes. As an illustrative example, non-limiting, for LEDs based on gallium nitride comprising quantum wells made of InGaN, a wavelength shift of the emission peak between a LED having a 4-μm width driven at a current density in the order of 200 A/cm² and a LED of same nature having a 25-μm width driven at a current density in the order of 10 A/cm², in the order of 30 nm can be observed. In this 30-nm shift, approximately 20 nm are linked to the size difference, the rest (approximately 10 nm) being linked to the current density difference. This shift is typically of the same order as the Stokes shift between the emission and the reception in the active stack.

It should be noted that the compensation by differentiation of the carrier densities between the LEDs and the photodiodes can also be obtained in a device having LEDs L of same lateral dimensions as photodiodes P, or even lateral dimensions greater than those of photodiodes P.

According to an aspect of a second embodiment, there is provided, before the common epitaxy step during which are simultaneously formed the active emission and reception stacks, to locally porosify, in front of the photodiodes of the device, a support layer made of a semiconductor material, on which is intended to be epitaxially grown the active stack. This results in a relaxation of the mechanical stress in the active stack of the photodiodes during the epitaxy, particularly during the forming of the active layer 103b of the stack. This relaxation results in a difference in the proportions of the species of the semiconductor alloy forming active layer 103b between the photodiodes and the LEDs. In particular, in the case where the active layer comprises quantum wells made of InGaN, this results in a higher incorporation of indium in the quantum wells of the photodiodes than in the quantum wells of the LEDs. This results in a red shift, that is, an upward shift, of the absorption peak of the photodiodes, and thus in at least partially compensating for the Stokes shift between the emission peak and the absorption peak of the active stack.

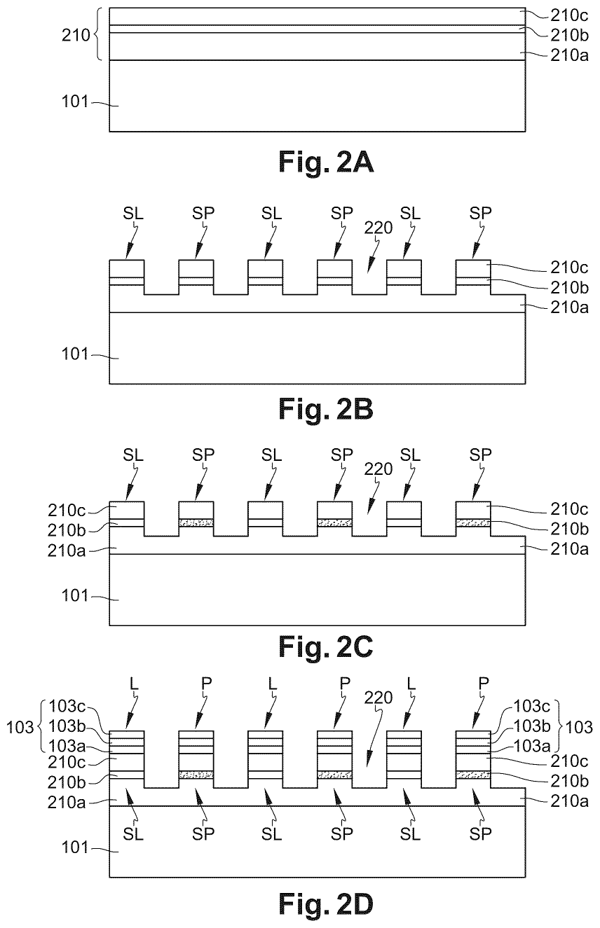

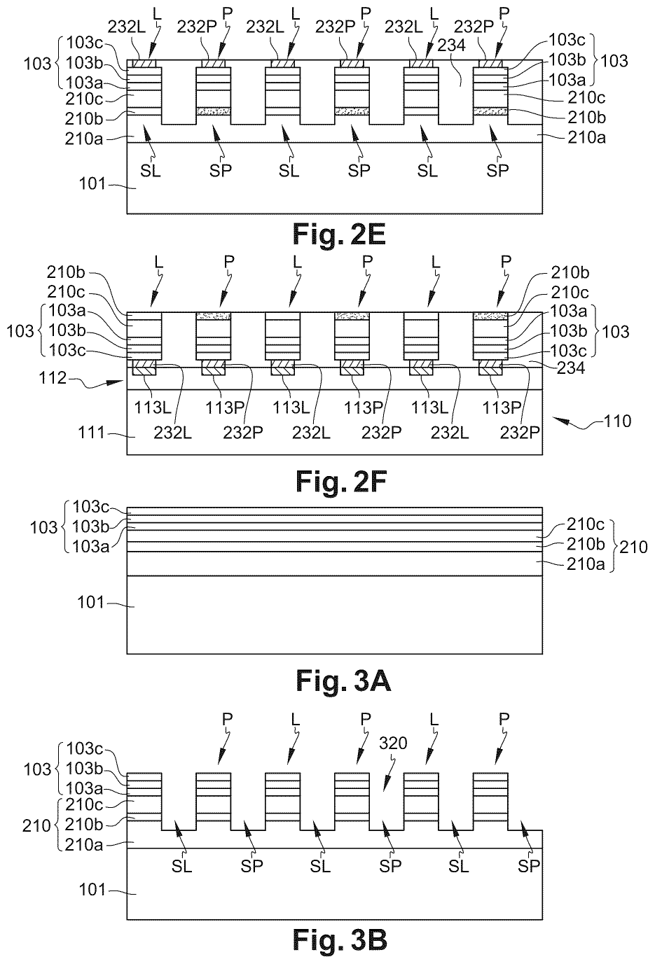

FIGS. 2A to 2F are cross-section views schematically illustrating steps of an example of implementation of a method of manufacturing an optoelectronic device according to the second embodiment.

FIG. 2A illustrates a structure comprising a support semiconductor stack 210 on a surface of a support substrate 101. Support substrate 101 is for example identical or similar to what has been previously described. Semiconductor support stack 210 is for example made of a type-III-V semiconductor material, for example made of gallium nitride. Semiconductor support stack 210 comprises at least one doped semiconductor layer 210b, having a doping level selected to enable to make layer 210b porous during a subsequent electrolytic porosification step. As an example, layer 210b is N-type doped. As an example, layer 210b is made of N-type doped gallium nitride having a doping level in the range from 10¹⁹ to 1.5*10¹⁹ atoms/cm³.

In the shown example, support stack 210 further comprises, on the lower surface side of layer 210b, for example in contact with the lower surface of layer 210b, a semiconductor layer 210a. Layer 210a is for example made of the same material as layer 210b but with a doping level lower than that of layer 210b, for example with a doping level at least ten times smaller, than that of layer 210b. As a variant, layer 210a is made of a material different from the material of layer 210b.

In the shown example, support stack 210 further comprises, on the upper surface side of layer 210b, for example in contact with the upper surface of layer 210b, a semiconductor layer 210c. Layer 210c is for example made of the same material as layer 210b but with a doping level lower than that of layer 210b, for example a doping level at least ten times lower, preferably at least 100 times lower, than that of layer 210b. As a variant, layer 210c is made of a material different from the material of layer 210b.

The layers 210a, 210b, and 210c of support stack 210 for example each continuously extend with a substantially uniform thickness over the entire surface of substrate 101.

Layers 210a, 210b, and 210c are for example successively formed by epitaxy on the upper surface of support substrate 101.

As an example, support substrate 101 is made of sapphire or of silicon. A buffer layer, not shown, may possibly form an interface between the upper surface of substrate 101 and the lower surface of the lower layer 210a of support stack 210.

FIG. 2B illustrates a step of forming of trenches 220 in support stack 210, from its upper surface, for example by lithography and then etching, to define in stack 210 a plurality of support pads SL and SP in the form of islands or mesas. Each support pad SL is intended to receive, on its upper surface, a LED L of the device, and each support pad SP is intended to receive, on its upper surface, a photodiode P of the device.

In the shown example, trenches 220 extend vertically from the upper surface de stack, thoroughly cross layers 210c and 210b, and emerge into layer 210a without thoroughly crossing it. As a variant, trenches 220 thoroughly cross layer 210.

Trenches 220 for example form, in top view, a grid or a checkered pattern laterally separating from one another the support pads SL and SP intended to receive the LEDs L and the photodiodes P of the device.

Support pads SP and SL for example all have the same lateral dimensions, for example in the range from 1 μm to 25 μm, for example from 2 to 8 μm. As an example, support pads SP and SL have, in top view, a square or rectangular shape.

At this stage, in each support pad SL and SP, the sides of the doped semiconductor layer 210b of the support stack are exposed.

FIG. 2C illustrates the structure obtained at the end of a step of selective porosification of layer 210b, only located in the support pads SP of the photodiodes P of the device. During this step, the layer 210b of support pads SP is made porous by electrolytic etching or electroporosification. The layer 210b of support pads SL however remains non-porous.

For this purpose, the sides of the support pads may be previously coated with a protection layer (not visible in the drawing), for example made of an insulating material, for example of oxide or of silicon nitride. The protection layer is for example initially deposited over the entire upper surface, and then locally removed, for example by photolithography and etching, to expose the sides of support pads SP without exposing the sides of support pads SL.

The structure can then be dipped into an electrolytic bath (not visible in the drawing), for example a solution based on oxalic acid, for example an aqueous solution of oxalic acid.

A bias voltage is then applied to conduct a current through doped semiconductor layer 210b. As an example, the voltage is applied between a first electrode (not visible in the drawing) connected to layer 210a and the electrolyte (not visible in the drawing) connected by the edge to layer 210c.

Under the effect of the bias current, the portions of layer 210b in contact, by their sides, with the electrolyte, that is, the portions of layer 210b contained in the support pads SP of the photodiodes P of the device, become porous. The portions of layer 210b protected from the contact with the electrolyte, that is, the portions of layer 210b contained in the support pads SL of the LED L of the device, however remain intact (non-porous).

It should be noted that, in this example, the doping levels of the layers 210a, 210b, and 210c of the support stack are selected so that only layer 210b is made porous during the electroporosification step.

At the end of this step, the protection layer coating the sides of support pads SL may be removed.

FIG. 2D illustrates the structure obtained at the end of a common epitaxy step during which is formed, on each support pad SL and on each support pad SP, an active semiconductor stack 103. The epitaxy is for example located in openings previously etched in a dielectric layer, not shown.

On each support pad SL and SP, active stack 103 for example covers the entire upper surface of the pad. The portion of active stack 103 coating each pad SL defines a LED of the device. The portion of active stack 103 coating each pad SP defines a photodiode of the device.

On each support pad SP and SL, active stack 103 comprises, in the order from the upper surface of the pad, a semiconductor layer 103a, a semiconductor layer 103b, and a semiconductor layer 103c, for example identical or similar to what has been previously described in relation with FIGS. 1A to 1D. Layers 103a, 103b, and 103c are for example successively formed by epitaxy from the upper surface of pads SP and SL. As an example, in each pad SP and SL, the lower semiconductor layer 103a of active stack 103 is in contact, by its lower surface, with the upper surface of layer 210c.

Due to the presence of porous layer 210b in support pads SP, a more significant mechanical relaxation is obtained in the active stack of photodiodes P than in the active stack of LEDs L. This results, during the epitaxy, in an incorporation of the different species in the active layer 103b of the active stack of LEDs L and in the active layer 103b of the active stack of photodiodes P. In particular, in the case of an active layer 103b based on InGaN, this results in a more significant incorporation of indium in the active layer 103b of photodiodes P than in the active layer 103b of LEDs L. Thus, the presence of porous layer 210b in the support pads SP of photodiodes P results in shifting the absorption peak of photodiodes P towards higher wavelengths (towards red), and thus in bringing it closer to the emission peak of LEDs L.

FIG. 2E illustrates the structure obtained at the end of a step of forming, on each LED L, of a contact metallization 232L on top of and in contact with the upper surface of the upper semiconductor layer 103c of the active stack 103 of the LED, and, on each photodiode P, of a contact metallization 232P on top of and in contact with the upper surface of the upper semiconductor layer 103c of the active stack 103 of the photodiode.

FIG. 2E further illustrates a step of filling of trenches 220 and of the space between LEDs L and photodiodes P with an electrically-insulating material 234, for example silicon oxide.

After the filling, a planarization step may be implemented, for example by chemical-mechanical polishing (CMP), so that contact metallizations 232L, 232P are flush with the upper surface of filling material 234.

FIG. 2F illustrates a step of transfer and of bonding of the structure of FIG. 2E onto an integrated control circuit 110, for example similar to that of FIG. 1B.

During this step, the contact metallizations 232L, 232P of the structure of FIG. 2E are placed into contact, by their surface opposite to support substrate 101, with the surface of the contact metallizations 113L, 113P of control circuit 110 opposite to substrate 111.

As an example, the structure of FIG. 2E is bonded and electrically connected to integrated control circuit 110 by molecular bonding, for example hybrid metal-to-metal/oxide-to-oxide bonding.

After assembly of the two structures, the support substrate 101 of the structure of FIG. 2E may be removed. Further, all or part of semiconductor support stack 210 may be removed, for example by grinding or etching.

In the shown example, the layer 210a of support stack 210 is fully removed, and layers 210b and 210c are kept. The described embodiments are however not limited to this example.

Subsequent steps may then be implemented to take an individual or common electric contact on the upper semiconductor layer 103a of the active stack 103 of each LED L and of each photodiode P. For example, a layer of a transparent electrically-conductive material, for example a transparent conductive oxide, for example indium-tin oxide (ITO) is deposited on top of and in contact with the upper surface of the structure of FIG. 2F. These steps have not been detail and are within the abilities of those skilled in the art based on the indications of the present description.

Similarly to what has been previously described, the control circuit may optionally be configured to drive the LEDs and the photodiodes with carrier densities adapted to decreasing the shift between the emission peak of the LEDs and the absorption peak of the photodiodes.

According to an aspect of a third second embodiment, it is provided to form support pads SP and SL similarly to what has been described hereabove in relation with FIGS. 2A to 2F, but to selectively porosify the layer 210b of the support pads only after the common epitaxy step during which are simultaneously formed the active stacks 103 of LEDs L and of photodiodes P. In this third embodiment, layer 210b is made porous vertically in line with LEDs L and is kept intact (non porous) vertically in line with photodiodes P. This results in at least partially relaxing the mechanical stress in the active stack of LEDs L without applying this relaxation in photodiodes P. This results in a decrease of the internal electric field in the active LED stack with respect to the internal electric field in the active photodiode stack. This decrease of the internal electric field in the active LED stack results in shifting downwards the emission peak of the LED. Here again, this enables to at least partially compensate for the Stokes shift between the emission peak and the absorption peak of the active stack. Thus, the emission peak of the LED comes closer to the absorption peak of the photodiode, which improves the system efficiency.

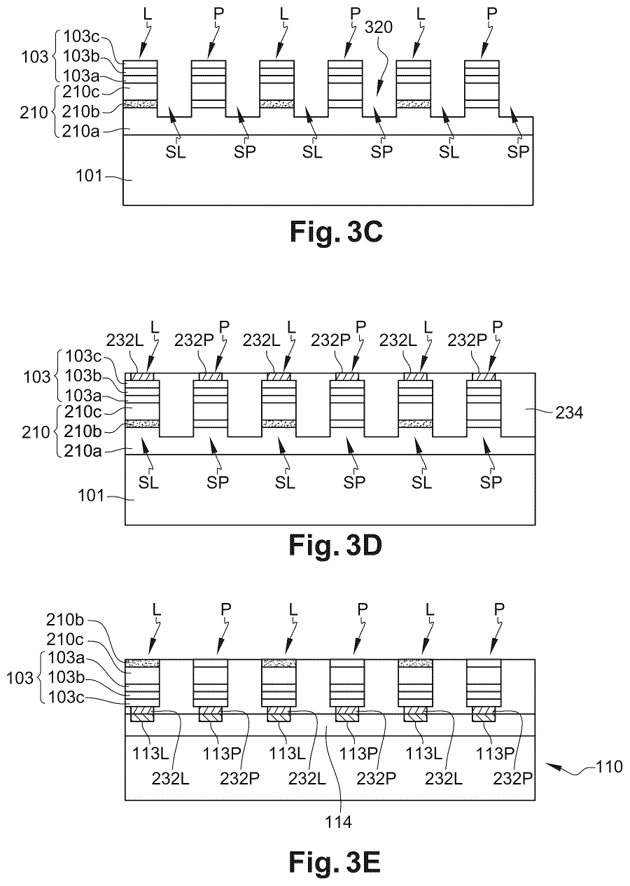

FIGS. 3A to 3E are cross-section views schematically illustrating steps of an example of implementation of a method of manufacturing an optoelectronic device according to the third embodiment.

FIG. 3A illustrates a structure comprising a support semiconductor stack 210 on a surface of a support substrate 101. Support stack 210 and support substrate 101 are for example identical or similar to what has been previously described in relation with FIG. 2A.

FIG. 3A further illustrates a step of forming of an active LED and photodiode stack 103 on the upper surface of semiconductor support stack 210. Active stack 103 is for example identical or similar to what has been previously described, particularly in relation with FIG. 1A. Layers 103a, 103b, and 103c are for example successively formed by epitaxy from the upper surface of support stack 210. As an example, the lower semiconductor layer 103a of active stack 103 is en contact, by its lower surface, with the upper surface of layer 210c.

At this stage, the layers of support stack 210 and the layers of active stack 103 each continuously extend with a uniform thickness over the entire surface of support substrate 101.

FIG. 3B illustrates a step of forming of trenches 320 in active stack 103 and in support stack 210, from the upper surface of active stack 103, for example by lithography and then etching, to define in stack 210 a plurality of support pads SL and SP in the form of islands or mesas, each support pad SL being coated, on its upper surface, with a portion of active stack 103 defining a LED L of the device, and each support pad SP being coated, on its upper surface, with a portion of active stack 103 defining a photodiode P of the device.

In the shown example, trenches 320 extend vertically from the upper surface of active stack 103, thoroughly cross layers 103c, 103b, 103a, 210c, and 210b, and emerge into layer 210a without thoroughly crossing it. As a variant, trenches 220 thoroughly cross layer 210.

Trenches 320 for example form, in top view, a grid or a checkered pattern laterally separating LEDs L and photodiodes P and support pads SL and SP.

LEDs L and photodiodes P, and the underlying support pads SP and SL, for example all have the same lateral dimensions, for example in the range from 1 μm to 25 μm, for example from 2 to 8 μm. As an example, LEDs L and photodiodes P and support pads SP and SL have, in top view, a square or rectangular shape. More generally, LEDs L and photodiodes P may have any shape, for example round or hexagonal.

At this stage, in each support pad SL and SP, the sides of the doped semiconductor layer 210b of the support stack are exposed.

FIG. 3C illustrates the structure obtained at the end of a step of selective porosification of layer 210b, only located in the support pads SL of the LEDs L of the device. This step is similar to what has been previously described in relation with FIG. 2C, with the difference that, in the example of FIG. 3C, the layer 210b of support pads SL is made porous, while the layer 210b of support pads SP remains intact (non-porous).

For this purpose, during the electroporosification step, the sides of support pads SP may be protected from the contact with the electrolyte by a protection layer (not visible in the drawing), the sides of support pads SL being however in contact with the electrolyte.

In the example of FIG. 3C, the bias voltage enabling to conduct a current through layer 210b is for example applied between a first electrode (not visible in the drawing) connected to layer 210a and the electrolyte (not visible in the drawing) connected by the edge to layer 103c.

Due to the porosification of layer 210b in support pads SL, a more significant mechanical relaxation is obtained in the active stack of LEDs L than in the active stack of photodiodes P. This results in shifting the emission peak of the LEDs downwards, and thus in bringing it closer to the absorption peak of photodiodes P.

FIG. 3D illustrates the structure obtained at the end of a step similar to what has been previously described in relation with FIG. 2E of forming, on each LED L, of a contact metallization 232L on top of and in contact with the upper surface of the upper semiconductor layer 103c of the active stack 103 of the LED, and, on each photodiode P, of a contact metallization 232P on top of and in contact with the upper surface of the upper semiconductor layer 103c of the active stack 103 of the photodiode.

FIG. 2E further illustrates a step of filling of trenches 320 and of the space between LEDs L and photodiodes P with an electrically-insulating material 234, for example silicon oxide.

Après the filling, a planarization step may be implemented, for example by chemical-mechanical polishing (CMP), so that contact metallizations 232L, 232P are flush with the upper surface of filling material 234.

FIG. 3E illustrates a step similar to what has been described hereabove in relation with FIG. 2F, of transfer and of bonding of the structure of FIG. 3D onto an integrated control circuit 110, and of removal of support substrate 101, and, possibly, of all or part of semiconductor support stack 210.

Similarly to what has been previously described, subsequent steps may then be implemented to take an individual or common electric contact on the upper semiconductor layer 103a of the active stack 103 of each LED L and of each photodiode P.

Similarly to what has been previously described, the control circuit may optionally be configured to drive the LEDs and the photodiodes with carrier densities adapted to decreasing the shift between the emission peak of the LEDs and the absorption peak of the photodiodes.

Various embodiments and variants have been described. Those skilled in the art will understand that certain features of these various embodiments and variants may be combined, and other variants will occur to those skilled in the art. In particular, the described embodiments are not limited to the examples of materials and of dimensions mentioned in the description.

Further, although there have been described hereabove examples of embodiments where the active LED and photodiode stacks 103 are bonded to the integrated control circuit by direct full plate metal-to-metal bonding or by direct hybrid metal-to-metal/dielectric-to-dielectric bonding, the described embodiments are not limited to these specific examples.

More generally, the active LED and photodiode stacks 103 may be bonded to the integrated control circuit by any other means, for example by direct full plate oxide-to-oxide bonding.

Further, it should be noted that the first and third embodiments may be combined.

Finally, the practical implementation of the described embodiments and variants is within the abilities of those skilled in the art based on the functional indications given hereabove.

What is claimed is:

1. Method of manufacturing an optoelectronic device comprising at least one LED and at least one photodiode, comprising the following steps:
a) forming a semiconductor support stack comprising at least one doped semiconductor layer;
b) simultaneously forming, during a common epitaxy step, an active emission semiconductor stack of the LED and an active reception semiconductor stack of the photodiode;
c) forming trenches vertically extending through the support stack and laterally delimiting at least one first support pad and at least one second support pad,
wherein, at the end of steps b) and c), the active emission semiconductor stack of the LED covers the first support pad and the active reception stack of the photodiode covers the second support pad,
the method further comprising, after step c), a step d) of porosification of said doped semiconductor layer in the first support pad without porosifying said doped semiconductor layer in the second support pad, or a step of porosification of said doped semiconductor layer in the second support pad without porosifying said doped semiconductor layer in the first support pad.

2. Method according to claim 1, wherein step c) of forming of the trenches through the support stack and step d) of porosification of the doped semiconductor layer are implemented before step b) of epitaxy of the active emission semiconductor stack of the LED and of the active reception semiconductor stack of the photodiode, and wherein, during step d), said doped semiconductor layer is porosified in the second support pad and is not porosified in the first support pad.

3. Method according to claim 1, wherein step c) of forming of the trenches through the support stack is implemented after step b) of epitaxy of the active emission semiconductor stack of the LED and of the active reception semiconductor stack of the photodiode, and wherein, during step d), said doped semiconductor layer is porosified in the first support pad and not in the second support pad.

4. Method according to claim 2, wherein, at step d), the sides of the doped semiconductor layer in the second pad are placed into contact with an electrolyte, while the sides of the doped semiconductor layer in the first pad are protected from the contact with the electrolyte by a protection layer.

5. Method according to claim 3, wherein, at step d), the sides of the doped semiconductor layer in the first pad are placed into contact with an electrolyte, while the sides of the doped semiconductor layer in the second pad are protected from the contact with the electrolyte by a protection layer.

6. Method according to claim 1, wherein, at step d), a bias current is applied through said doped semiconductor layer.

7. Method according to claim 1, comprising, after steps b) and d), a step of transfer and of bonding of the LED and of the photodiode onto a surface of an integrated control circuit previously formed inside and on top of a semiconductor substrate.

8. Method according to claim 7, wherein during said transfer and bonding step, the LED and the photodiode are bonded to said surface of the integrated control circuit by molecular bonding.

9. Method according to claim 1, wherein the trenches are arranged so that the lateral dimensions of the LED are smaller than the lateral dimensions of the photodiode.

10. Method according to claim 1, wherein the active emission semiconductor stack of the LED and the active reception semiconductor stack of the photodiode comprise one or a plurality of type-III-V or II-VI semiconductor alloys.

11. Optoelectronic device comprising at least one LED comprising an active emission semiconductor stack and at least one photodiode comprising an active reception semiconductor stack, the device further comprising a doped semiconductor layer in front of the LED and of the photodiode, wherein the doped semiconductor layer is porous in front of the LED and non-porous in front of the photodiode, or wherein the doped semiconductor layer is porous in front of the photodiode and non-porous in front of the LED.

12. Device according to claim 11, further comprising an integrated control circuit on a surface of which are bonded the LED and the photodiode, the integrated control circuit being adapted to driving the LED with a current density higher than that of the photodiode.

13. Device according to claim 12, wherein the integrated control circuit is adapted to driving the LED with a current density at least ten times higher than that of the photodiode.
